(19) United States
(12) Patent Application Publication
(10) Pub. No.: US 2026/0016437 A1
(43) Pub. Date: Jan. 15, 2026

(54) ELECTRICAL TOMOGRAPHY SYSTEMS AND USES

(71) Applicant: Syngenta Crop Protection AG, Basel (CH)

(72) Inventor: Gerald Roger DUCATTE, JR., Greensboro, NC (US)

(73) Assignee: Syngenta Crop Protection AG, Basel (CH)

(21) Appl. No.: 18/861,620

(22) PCT Filed: May 15, 2023
(86) PCT No.: PCT/US23/22239

§ 371 Date: Oct. 30, 2024

Related U.S. Application Data
(60) Provisional application No. 63/342,282, filed on May 16, 2022.

(51) Int. Cl. G01N 27/22; A01C 23/00; G01N 1/28; G01R 35/00; G08B 21/18

(52) U.S. Cl. CPC G01N 27/221; A01C 23/007; G01N 1/286; G01N 27/226; G01R 35/005; G08B 21/182; G01N 2001/2866

(57) ABSTRACT

Systems and methods are disclosed for monitoring a status of a composition containing an agrochemical active ingredient in real time.

### CROSS-REFERENCE TO RELATED APPLICATIONS

This application claims the benefit of U.S. Provisional Patent Application 63/342,282, filed May 16, 2022, the entire contents of which are incorporated by reference herein.

### TECHNICAL FIELD

Various embodiments of the present disclosure pertain generally to monitoring the homogeneity of a liquid or liquid/solid mixture over time. More specifically, particular embodiments of the present disclosure relate to systems and methods for determining the homogeneity of a liquid or liquid/solid mixture based on an electric potential applied to the liquid.

### BACKGROUND

Protecting and cultivating agriculture products requires application of a number of different crop protection products. These products are often a mixture of materials that are combined, stored, and applied in tanks of various sizes. During application of a product to a field, it is necessary for the product to remain thoroughly mixed, to ensure a homogenous product is uniformly applied. Mixtures are known to separate over time, especially in response to a change in temperature during storage or application. Additionally, relatively stable mixtures can become less stable as they are diluted with water or are mixed with fertilizers or other tank mix chemicals immediately before application to a field. As sedimentation or liquid layering of a mixture occurs, the mixture becomes less effective for the application to a crop field. Sedimentation can also result in the build-up of solids in tubing and/or nozzles on the application equipment as the system pumps product (sucking from the bottom of the tank) through the spray apparatus.

The background description provided herein is for the purpose of generally presenting the context of the disclosure. Unless otherwise indicated herein, the materials described in this section are not prior art to the claims in this application and are not admitted to be prior art, or suggestions of the prior art, by inclusion in this section.

### SUMMARY

According to certain aspects of the present disclosure, systems and methods are disclosed for monitoring the status of a mixture in real time.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various embodiments and together with this description, serve to explain the principles of the disclosed embodiments.

FIG. 1 is a flowchart of a method for monitoring a homogeneity index of a mixture, according to an embodiment of the present disclosure.

FIG. 2 is a flowchart of a method for determining a maximum homogenous value of a mixture, according to an embodiment of the present disclosure.

FIG. 3 is an embodiment of a vertically oriented tank with a series of sensors.

FIG. 4 is a layout of sensors around horizontal rings of a vertical tank.

FIG. 5 is an embodiment of a horizontally oriented tank with a series of sensors.

FIGS. 6A and 6B are layouts of sensors around a plurality of ring sections of a horizontally oriented tank, according to embodiments of the present disclosure.

FIG. 7 shows an embodiment of the disclosure in use for agrochemical application.

### DETAILED DESCRIPTION OF ILLUSTRATIVE EMBODIMENTS

Reference will now be made in detail to embodiments of the present disclosure, examples of which are illustrated in the accompanying drawings. Wherever possible, the same reference numbers will be used throughout the drawings to refer to the same or like parts.

The systems, devices, and methods disclosed herein are described in detail by way of examples and with reference to the figures. The examples discussed herein are examples only and are provided to assist in the explanation of the apparatuses, devices, systems, and methods described herein. None of the features or components shown in the drawings or discussed below should be taken as mandatory for any specific implementation of any of these devices, system, or methods unless specifically designated as mandatory.

Also, for any methods described, regardless of whether the method is described in conjunction with a flow diagram, it should be understood that unless otherwise specified or required by context, any explicit or implicit ordering of steps performed in the execution of a method does not imply that those steps must be performed in the order presented but instead may be performed in a different order or in parallel. As used herein, the term “exemplary” is used in the sense of “example,” rather than “ideal.” Moreover, the terms “a” and “an” herein do not denote a limitation of quantity, but rather denote the presence of one or more of the referenced items.

As used herein, agrochemicals include, but are not limited to herbicides, fungicides, insecticides, bactericides, insect growth regulators, plant growth regulators, nematicides, molluscicides or mixtures of several of these preparations. In general, agrochemicals are components which illicit a recognized, intended biological response in crops or pests to crops.

An agrochemically effective amount refers to an amount of agrochemical approved or recognized for achieving the intended result of the agrochemical. For example, a fungicidally effective amount is an amount of fungicide which is approved for or recognized as controlling or curing a phytopathogenic fungal infection.

Compositions, particularly those for analysis in the vessel, can be in various physical forms as well as dilutions and mixtures thereof, as understood by a person of ordinary skill in the art, e.g. in the form of gels, wettable powders, water-dispersible granules, water-dispersible tablets, effervescent pellets, emulsifiable concentrates, microemulsifiable concentrates, oil-in-water emulsions, oil-flowables, aqueous dispersions, oily dispersions, suspo-emulsions, capsule suspensions, emulsifiable granules, soluble liquids, and water-soluble concentrates (with water or a water-miscible organic solvent as carrier).

A product delivery score is a rating which reflects the suitability of transferring/applying the contents of a vessel. The product delivery score can be based in-part on the homogeneity index score. The product delivery score can further take into account other environmental conditions such as temperature (ambient or of the contents of the vessel). In specific embodiments, the transferring or applying of the contents of the vessel can be modified to raise the product delivery score.

Protecting and cultivating agriculture products requires application of a number of different crop protection products. Often, these products are a mixture of a liquid and one or more liquid or solid materials, which are combined, stored, and applied in large tanks. During application of a product to a field, it is critical for the product to remain thoroughly mixed, so that a homogenous product is uniformly applied to a crop field. Certain types of agricultural formulations are known to separate over time, especially in response to a change in temperature during storage or application. Additionally, relatively stable mixtures can become less stable as they are diluted with water or are mixed with fertilizers or other tank mix chemicals immediately before application to a field. As sedimentation of a mixture occurs, the mixture becomes less effective for the application to a crop field, and the pumping of sediment through the spray system can cause plugging of tubing and nozzles. Further, mixtures can foam in response to mixing, causing additional issues during application of the crop protection product.

The product homogeneity, or mixing/settling status of the product, in a tank is traditionally determined by a visual inspection of the mixture in the tank, or by pulling a sample from the mixture to inspect. Conclusive visual assessments are particularly difficult, if not impossible, for mixtures that are opaque. This requires a user to open a sealed tank to inspect the mixture or to pull a sample of the mixture for testing. Pulling a sample from the tank is a significant challenge in the storage setting, and can allow for foreign material to enter the tank through exposure to workers looking to detect settling in the sample. The visual inspection process can delay the application of the mixture, and can be subject to user error. Further, the visual inspection only assesses the homogeneity of the mixture at a single point prior to or during application, as opposed to continual monitoring of the homogeneity of the mixture as it is applied.

Real-time, quantitative characterization of formulation stability and homogeneity of a mixture after addition or subtraction of one or more ingredients assures a user that a well-mixed, homogenous product is being applied to the crop field. Sedimentation may occur after application equipment has been left for some time, for example when the application equipment is inactive in the field. Foaming may also occur and impact the product's homogeneity level. An on-the-fly assessment of the product's homogeneity allows the user to know if and/or when a well-mixed product is applied, and allows for users to troubleshoot issues. The same monitoring system allows for the real-time, quantitative characterization of resuspension strategies (i.e., agitation arrangement, speed and/or flow settings, etc.) for neat, diluted, or modified product in order to identify optimized mixing or resuspension parameters. Non-stop, automated data collection additionally assesses the physical stability of neat products, and allow for the optimization of storage systems and storage timelines. In some embodiments, data collection occurs on the order of once every second, once every ten second, once every 30 second, once every minute, once every 2 minutes, etc.

The present disclosure allows for mixing without visual inspection or physical collection of samples, through the use of electrical tomography. “Electrical tomography” refers to electrical tomographic investigation methods, such as electrical tomographic imaging, covering various methods for investigating or monitoring a target region on the basis of determining an estimation of an electrical property of interest of one or more materials present in the target region. Generally, the target region is a two-dimensional area or a three-dimensional volume. Said determination is carried out on the basis of non-invasive measurements of a measurable electrical quantity which may be the electrical property of interest itself, or a secondary, measurable electrical quantity dependent on, or proportional to, the actual property of interest.

The electrical property of interest can be, for example, electrical permittivity or conductivity. In a preferred embodiment, the tomography process falls within electrical capacitance tomography ECT or electrical impedance tomography EIT, respectively. In yet another possibility, the electrical property of interest may be electrical admittivity, combining those two above quantities. The admittivity can be a complex valued quantity. However, the electrical property of interest is not limited to the examples above.

Electrical tomography can be based, for example, on comparison of measured values of the measurable electrical quantity and corresponding simulations provided by an observation model for an approximation of the electrical property of interest conditions in the target region. An estimate of the property of interest may be determined in an iterative process comprising adjustment of the observation model on the basis of such comparison. Thereby, the property of interest conditions within the target region can be reconstructed.

The estimated and thereby “determined” property of interest may be used as an indication of various material conditions in the target volume. For example, abrupt changes in the property of interest indicates boundaries between different material phases. Such boundaries provide information, for example, on the sedimentation of or mixing of such different materials or material phases.

The present disclosure allows for the homogeneity index of a mixture to be monitored in real time using electrical tomography. Electrical tomography can determine the conductivity of the mixture by applying an electrical potential across the mixture and measuring the resulting conductivity of the mixture to determine whether sedimentation or liquid layering has occurred. This conductivity can be output to a processor in a remote device for storage and display to the user. The potential is applied by sensors placed through the outside wall of a tank storing the mixture, where the sensors are oriented in a specific layout to obtain an accurate reading for the entire volume of the mixture. Each sensor comprises an electrode, which may alternate functioning as a cathode or anode as needed. A homogeneity index within a subsection of the tank may be obtained by eliminating measurements from sections of the tank that already contain sediment, empty space (air), or other layering. In some orientations, a higher number of sensors are placed on a bottom of the application tank to allow for enhanced spatial discrimination in that area of the tank to determine regions of minimal product settling versus regions of prominent product settling. Alternatively, a higher number of sensors are placed near the top of a tank to determine if significant foaming has occurred. This data helps assess mixing and settling dynamics of a specific tank design.

The present disclosure may be versatile enough for application to a range of agricultural mixture conductivities, from 1 mS/cm to hundreds of mS/cm. The working range may extend beyond these values depending on specific hardware and data processing parameters. Specifically, the method can accommodate neat pesticide formulations as well as those diluted with high-conductivity ingredients such as fertilizers. The method allows for monitoring of different materials without calibration. In the present disclosure, the method requires an initial calibration based on the tank geometry.

The present disclosure allows for a user to view real-time data on a display as the product is applied. Data can be displayed as a two-dimensional or three-dimensional rendering of the volume, or as a plot of the mixture's homogeneity index or conductivity over time. A processor attached to the sensors sends the measured data to display on the tank holding the mixture, or to a remote device for monitoring from a distance while the mixture is applied.

The present disclosure allows for the tracking of product homogeneity during storage as well as during application. For example, the method can be applied to products stored within tanks in a storage facility to assess physical stability of neat products. Remote monitoring of physical stability of products may include an alert to inform a tank steward when tank agitation is needed. This may prevent the removal or distribution of product fractions that do not contain all ingredients at a correct concentration. Alternatively, this method allows for automated remote monitoring where a software program monitors the homogeneity status of the product, activates an agitation mode when the homogeneity status is determined to be outside of a predetermined threshold, and stops agitation when a target homogeneity is achieved. Embodiments of the disclosure can be utilized in agrochemical application equipment, such as tanks in/on tactors, drones (aerial or terrestrial), or any other equipment utilized to apply agrochemicals from a tank to an area of interest. While agrochemical application equipment can be configured for areas having limited space, assemblies on planters, or indoor growing spaces which can be automated, preferred agrochemical application equipment is designed for applying agrochemicals over large areas such as at least 5 acres, at least 10 acres, at least 20 acres, at least 50 acres, at least 100 acres, at least 500 acres, or at least 1,000 acres. Application over larger areas require more time, and therefore, risk of settling or separation is greater. For areas of cultivation having limited areas, it is often difficult to prepare the exact amount of agrochemical necessary for application. Accordingly, embodiments of the disclosure can monitor homogeneity for at least a week, at least two weeks, or even at least one-month.

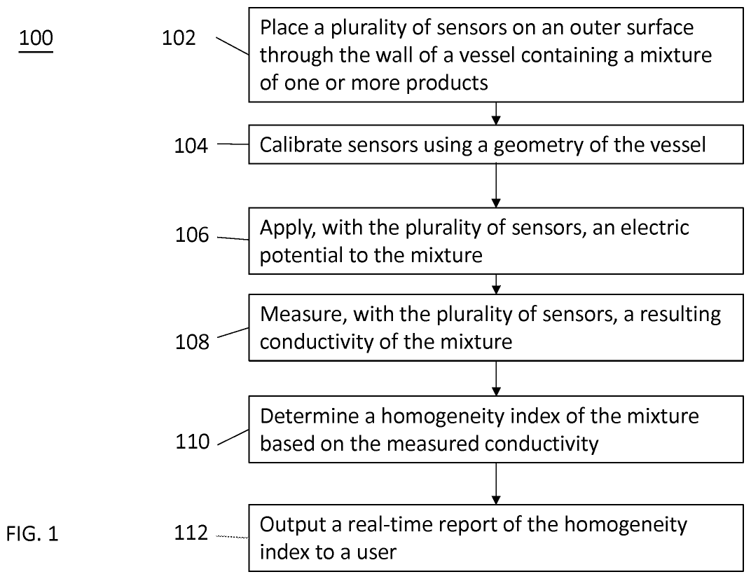

FIG. 1 is an exemplary flowchart of a method of monitoring the homogeneity of a mixture, according to an exemplary embodiment of the present disclosure. For example, an exemplary method 100 (e.g., steps 102 to 112) may be performed by a processor 204 automatically or in response to a request from a user.

The exemplary method 100 for monitoring the homogeneity of a mixture may include one or more of the following steps. In step 102, the method may include placing a plurality of sensors, such as sensors 218, on an outer surface through the wall of a vessel, such as vertical tank 200, containing a mixture of one or more products. The sensors can be placed in concentric rings around the circumference of the vessel, and may be staggered in orientation to provide a better reading of the target volume, as discussed below.

In step 104, the method may include calibrating the plurality of sensors based on a geometry of the vessel. The geometry of the vessel comprises the shape, dimensions, and inner volume of the vessel itself as well as the specific placement of tomography sensors. Since the calibration is dependent on this geometry and not on the properties of the mixture within the vessel, a wide range of mixtures can be used in conjunction with exemplary method 100 without requiring any additional calibration process.

In step 106, the method may include applying, with the plurality of sensors, an electric potential to the mixture. The plurality of sensors can be directed to apply the potential automatically by a processor, or in response to a command from a user. Each sensor comprises an electrode, which may alternate functioning as a cathode or anode as needed.

In step 108, the method may include measuring, with the plurality of sensors, a resulting conductivity of the mixture. The plurality of sensors is directed to take the measurement automatically by a processor, or in response to a command from a user. The plurality of sensors may take measurements simultaneously, or only certain sensors may take measurements of specific regions of the mixture. By breaking the mixture into regions, a user is able to determine what occurs in that area of the mixture as sedimentation occurs. For example, a region near the bottom of the vessel may be subject to higher levels of sedimentation than a region near the top of the vessel. Eliminating/ignoring the signal from sensors in the vicinity of the sediment will allow a more thorough assessment of homogeneity within upper levels of the tank.

Different levels of conductivity within the mixture represent different levels of homogeneity of the mixture. A homogenous mixture can have the same conductivity throughout, whereas a mixture that has begun to settle may be more or less conductive. The first measurement the plurality of sensors take may represent a “thoroughly mixed” mixture, that has no or minimal sedimentation, liquid layering, or loss of suspension. Measurements taken by the sensor after the mixture begins to separate show how rapidly sedimentation occurs, or how the level of sedimentation is affected by the change in ambient temperature as the mixture is applied.

Specific embodiments of the disclosure include the following

Embodiment 1A. A method for monitoring a status of a mixture in real time, the method comprising:
placing a plurality of sensors through a wall of a vessel, the vessel containing a mixture of one or more products;
calibrating the plurality of sensors based on a geometry of the vessel;
using the plurality of sensors to apply an electric potential to the mixture;
measuring, using the plurality of sensors, a conductivity of the mixture resulting from the applied electric potential;
determining a homogeneity index score of the mixture based on the measured conductivity; and
outputting a real-time report of the homogeneity index to a user.

Embodiment 2A. The method of Embodiment 1A, further comprising: diluting the mixture with one or more liquid products;
mixing the mixture and the one or more liquid products until a predetermined suspension parameter is met;
sealing the vessel;
applying an electric current through the mixture;
measuring the conductivity of the mixture;
determining the homogeneity index of the mixture; and
recording the resulting homogeneity index as a maximum homogenous value that can be achieved for the mixture.

Embodiment 3A. The method of Embodiment 2A, further comprising: setting a threshold value from the maximum homogeneous value of the mixture
monitoring the homogeneity index of the mixture over time;
determining whether the homogeneity index has crossed the threshold value; and
alerting a user to reagitate the mixture.

Embodiment 4. The method of Embodiment 1A, wherein the real-time report comprises at least one of a two-dimensional rendering of the mixture in real time, a three dimensional rendering of the mixture in real time, and/or a real time plot of the homogeneity index over time.

Embodiment 5A. The method of Embodiment 1A, wherein the plurality of sensors are placed around a circumference of the vessel.

Embodiment 6A. The method of Embodiment 5A, where a majority of the plurality of sensors are placed near a bottom part of the vessel.

Embodiment 7A. The method of Embodiment 1A, wherein the homogeneity index is a value between zero and one.

Embodiment 8A. The method of Embodiment 1A, further comprising:
dividing the mixture within the vessel into subsections;
filtering out measurements from one or more subsections of the vessel containing a sediment or other layering; and
determining a homogeneity index of a subsection of interest.

Embodiment 9A. The method of Embodiment 1A, wherein the plurality of sensors are electrodes.

Embodiment 10A. The method of Embodiment 1A, further comprising:
determining the mixture is at a sufficiently well-mixed state; and
applying the mixture to a field.

Embodiment 11A. The method of Embodiment 1A, further comprising placing an additional number of sensors on a bottom of the vessel.

Embodiment 12A. The method of Embodiment 11A, wherein the additional number of sensors are configured to identify one or more regions of minimal settling at the bottom of the vessel.

Embodiment 1B. A method of monitoring formulation stability in real time, comprising:
A. loading a vessel comprising a plurality of sensors on a wall of the vessel with a composition comprising at least one agrochemical;
B. applying an electrical potential with the plurality of sensors to the contents of the vessel;
C. measuring with the plurality of sensors at least one electrical property of the contents of the vessel from the applied electric potential;
D. determining a homogeneity index score of the contents of the vessel based on the at least one electrical property; and
E. outputting a real-time report of the homogeneity index score.

Embodiment 2B. The method of Embodiment 1B, further comprising calibrating the plurality of sensors based on a geometry of the vessel.

Embodiment 3B. The method of Embodiments 1B or 2B, further comprising calibrating the plurality of sensors based on a fill level of the vessel.

Embodiment 4B. The method of any one of Embodiments 1B-3B, further comprising diluting the composition in the vessel with carrier liquid, preferably water.

Embodiment 5B. The method of any one of Embodiments 1B-4B, further comprising loading a second composition comprising at least one agrochemical, wherein the at least one agrochemical of the second composition is different from the at least one agrochemical of the composition.

Embodiment 6B. The method of any one of Embodiments 1B-5B, further comprising agitating the vessel, optionally wherein the agitating is before or after the determining of the homogeneity index score.

Embodiment 7B. The method of Embodiment 6B, wherein the agitating is in response to the homogeneity index score, and optionally agitating the contents of the vessel until a predetermined homogeneity index score is achieved.

Embodiment 8B. The method of any one of claims 1B-7B, wherein the at least one electrical property includes electrical conductivity.

Embodiment 9B. The method of any one of Embodiments 1B-8B, further comprising calibrating the plurality of sensors based on a geometry of an X, a Y, and a Z positional assignment for at least two of the sensors.

Embodiment 10B. The method of any one of claims 1B-9B, further comprising determining a product delivery score based on the homogeneity index score.

Embodiment 11B. The method of any one of Embodiments 1B-10B, further comprising recording a maximum homogenous value for the contents of the vessel.

Embodiment 12B. The method of any one of Embodiments 1B-11B, further comprising applying an electrical current to the contents of the vessel.

Embodiment 13B. The method of any one of Embodiments 1B-12B, further comprising:
setting a threshold value from the maximum homogeneous value of the contents of the vessel;
monitoring the homogeneity index of the contents of the vessel over time;
determining whether the homogeneity index has crossed the threshold value; and
alerting a user to agitate the contents of the vessel and/or stop transfer/application of the contents of the vessel.

Embodiment 14B. The method of any one of Embodiments 1B-12B, further wherein the real-time report comprises at least one of a two-dimensional rendering of the mixture in real time, a three dimensional rendering of the mixture in real time, and/or a real time plot of the homogeneity index over time.

Embodiment 15B. The method of any one of Embodiments 1B-14B, wherein the plurality of sensors are around a circumference of the vessel.

Embodiment 16B. The method of any one of Embodiments 1B-15B, wherein the plurality of sensors comprise at least eight sensors or sensor strips.

Embodiment 17B. The method of any one of Embodiments 1B-16B, where a majority of the plurality of sensors are near a bottom part of the vessel or a transfer port of the vessel.

Embodiment 18B. The method of any of Embodiments 1B-17B, further comprising:
dividing the contents within the vessel into a plurality of subsections;
filtering out measurements from one or more subsections of the vessel containing a sediment or other layering; and
determining a homogeneity index of one of the plurality of subsections.

Embodiment 19B. The method of any one of Embodiments 1B-18B, wherein the plurality of sensors are electrodes.

Embodiment 20B. The method of any one of Embodiments 1B-19B, further comprising applying the contents of the vessel from an agrochemical applicator, preferably a nozzle, in fluid communication with the vessel to a crop or locus thereof.

Embodiment 21B. The method of any one of Embodiments 1B-20B, wherein the vessel is a part of agrochemical application equipment, preferably a tractor.

Embodiment 22B. The method of any one of Embodiments 1B-21B, further comprising modifying at least one component of the composition based on the homogeneity index score, and optionally repeating A-E.

Embodiment 23B. The method of any one of Embodiments 1B-22B, further comprising transferring the bulk contents of the vessel to a second bulk vessel.

Embodiment 24B. A system for monitoring formulation stability in real time, comprising:
a vessel formed from at least one wall and preferably configured to hold at least 1 gallon, at least 5 gallons, at least 10 gallons, at least 100 gallons, at least 1,000 gallons, or at least 10,000 gallons;
a plurality of sensors along a wall of the vessel configured to apply an electrical potential to the contents of the vessel and measure at least one electrical property of the contents of the vessel;
a processor in communication with the plurality of sensors and configured to determine a homogeneity index score of the contents of the vessel based on the at least one electrical property; and
a composition contained within the vessel, wherein the composition contains at least one agrochemical active ingredient.

Embodiment 25B. The system of Embodiment 24B, further comprising at least one agitator configured to agitate the contents of the vessel, wherein the agitator is preferably a propeller in the vessel.

Embodiment 26B. The system of Embodiments 24B or 25B, wherein the plurality of sensors are configured to measure electrical conductivity.

Embodiment 27B. The system of any one of Embodiments 24B-26B, further comprising a processor configured to determine a product delivery score based on the homogeneity index score.

Embodiment 28B. The system of any one of Embodiments 24B-27B, wherein the processor is configured to determine a maximum homogenous value for the contents of the vessel.

Embodiment 29B. The system of any one of Embodiments 24B-28B, wherein the plurality of sensors are configured to apply an electrical current to the contents of the vessel.

Embodiment 30B. The system of any one of Embodiments 24B-29B, further comprising a memory space in communication with a processor or the plurality of sensors, and configured to store information from the plurality of sensors and/or processor.

Embodiment 31B. The system of any one of Embodiments 24B-30B, further comprising a display capable of displaying the homogeneity index score or information derived therefrom.

Embodiment 32B. The system of Embodiment 31B, wherein the display provides at least one of a two-dimensional rendering of the contents of the vessel in real time, a three dimensional rendering of the contents of the vessel in real time, and/or a real time plot of the homogeneity index over time.

Embodiment 33. The system of any one of Embodiments 24B-32B, wherein the plurality of sensors are around a circumference of the vessel.

Embodiment 34B. The system of any one of Embodiments 24B-33B, wherein the plurality of sensors comprise at least six sensors.

Embodiment 35B. The system of any one of Embodiments 24B-34B, where a majority of the plurality of sensors are near a bottom part of the vessel or a transfer port of the vessel

Embodiment 36B. The system of any one of Embodiments 24B-35B, wherein the plurality of sensors are electrodes.

Embodiment 37B. The system of any one of Embodiments 24B-36B, further comprising an agrochemical applicator, preferably a nozzle, in fluid communication with the vessel.

Embodiment 38B. The system of Embodiment 37B, wherein a processor controls application of the contents of the vessel from the agrochemical applicator based on the homogeneity index score or information derived therefrom.

Embodiment 39B. The system of any one of Embodiments 24B-38B, wherein the vessel is a part of agrochemical application equipment, preferably a tractor.

Embodiment 40B. The system of any one of Embodiments 24B-39B, further comprising a second vessel in communication with the vessel and configured to modify the contents of the vessel based on the homogeneity index score or information derived therefrom.

In step 110, the method may include determining a homogeneity index of the mixture based on the measured conductivity. The homogeneity index can be a number between zero and one, where one represents a perfectly homogenous mixture. However, the homogeneity index can be any representation which reflects the homogeneity of the composition/mixture, for example a gradient of colors from green to red, or a binary output of homogenous or non-homogenous, or as discussed below 2D and 3D representations of the contents of the tank. As the homogeneity value drops over time, the mixture becomes more settled and experience higher instances of sedimentation and/or liquid layering. The initial homogeneity index value for a mixture may be less than one, depending on the products in the mixture. This initial value is stored by a processor as a baseline to compare with subsequent homogeneity indices, or to prepare a profile of the homogeneity of a mixture changing over time. The data collection system may be capable of collecting data several times per second and producing plots and images every few seconds. This data collection/processing frequency allows for high temporal resolution relative to typical settling/layering events observed in agricultural formulations (settling can begin in agricultural formulations within minutes after stirring).

In step 112, the method may include outputting a real-time report of the homogeneity index of the mixture to a user. The homogeneity index data can be displayed as a two-dimensional or three-dimensional rendering of the volume, or as a plot of the mixture's homogeneity index or conductivity over time. The presence of foam within the mixture is indicated by a layer at the top of the two- or three-dimensional renderings, as well as a decreased homogeneity level. The processor attached to the sensors sends the measured data to display on the tank holding the mixture, or to a remote device for monitoring from a distance while the mixture is applied.

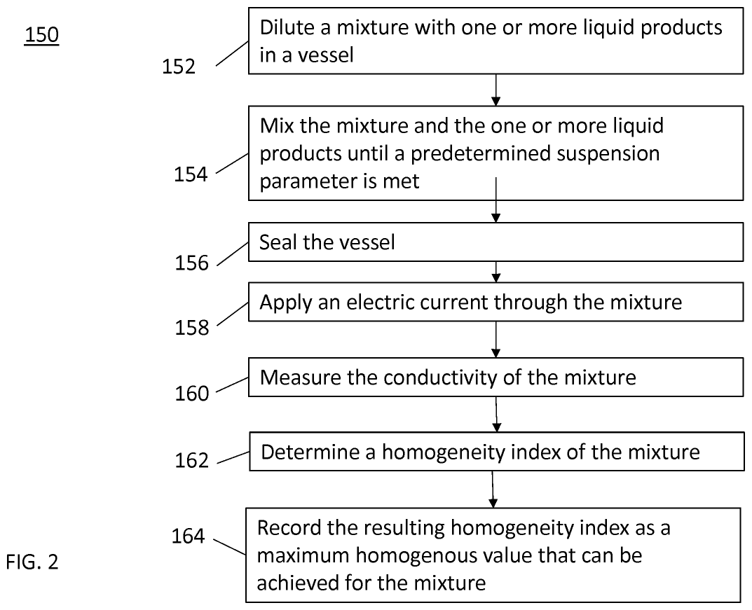

FIG. 2 is an exemplary flowchart of a method of determining the maximum homogeneity of a mixture, according to an exemplary embodiment of the present disclosure. For example, an exemplary method 150 (e.g., steps 152 to 164) may be performed by a processor 204 automatically or in response to a request from a user.

The exemplary method 150 for determining the maximum homogeneity of a mixture may include one or more of the following steps. In step 152, the method may include diluting a mixture with one or more liquid products within a vessel, such as tank 200. The one or more liquid products include a variety of agrochemical products for application to a crop field.

In step 154, the method may include stirring/agitating the mixture and the one or more liquid products until a predetermined suspension parameter is met. The predetermined suspension parameter corresponds to the mixture and the products, such that each individual mixture has a suspension parameter determined by the products added to the mixture, or by the characteristics of the mixture itself. The predetermined suspension parameter may represent a perfectly mixed mixture with no sedimentation or liquid layering present, or a mixture with an acceptable level of sedimentation or liquid layering present. Once this parameter is met, the vessel is sealed in step 156. Some vessels have built-in agitation systems or tubing that allows for resuspension or mixing while the vessel remains closed.

In step 158, the method may include applying an electric current through the mixture, similarly to the electric current applied in method 100. Likewise, method 150 may include the step 160 of measuring the conductivity of the mixture and the step 162 of determining a homogeneity index of the mixture, as described in method 100.

In step 164, the method may include recording the resulting homogeneity index as a maximum homogenous value that can be achieved by the mixture. The maximum homogenous value is between zero and one, and represents the homogeneity index of the mixture when the mixture is at its most thoroughly mixed level.

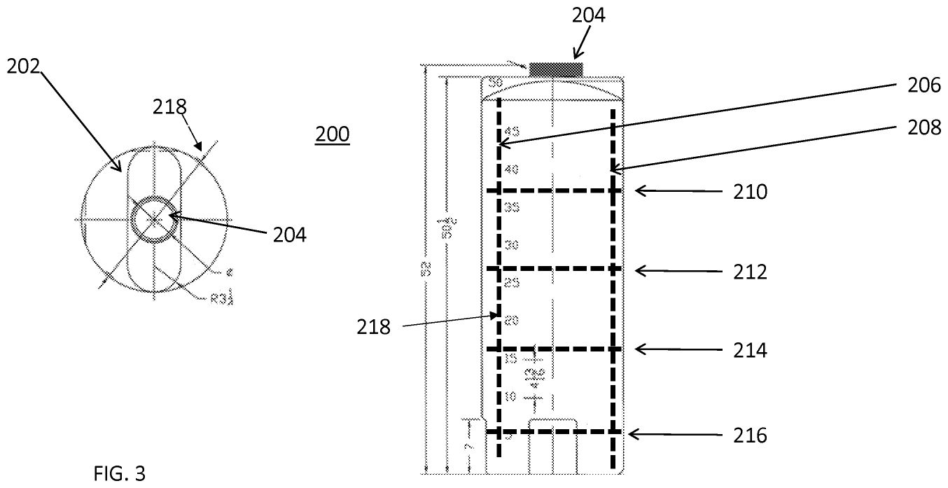

FIG. 3 is an exemplary embodiment of a vertically oriented vessel with a series of sensors. The vessel, or vertical tank 200, has a cylindrical shape and may be of the exemplary dimensions indicated. The vertical tank can be a 50-gallon plastic application tank, although any suitable tank of any size may be used to hold the mixture for storage or application. The vertical tank 200 has a plurality of sensors 218 spaced evenly apart from one another, in a series of vertical strips or horizontal rings. In an exemplary embodiment, 64 sensors 218 are oriented around the vertical tank 200. The sensors 218 are in communication with a processor 204, may be placed on a cover 202 of the vertical tank 200. As discussed above, processor 204 stores information from the sensors 218 and determine a homogeneity index of the mixture contained within the vertical tank 200.

Vertical strip 206 comprises a number of sensors 218, and may be oriented parallel to a second vertical strip 208. The purpose of the sensors 218 on each of the vertical strips 206 and 208 is to maximize the ability to measure the vertical profile of the mixture across the tank. In an exemplary embodiment, each strip contains 16 sensors 218, with each sensor 218 spaced 8 cm from the next. Vertical strips 206 and 208 may be located on opposite sides of the vertical tank 200, with a 180 degree angle between them, as shown on the overhead image of vertical tank 200. The starting point of vertical strip 206 may be lower than the starting point of the second vertical strip 208. In an exemplary embodiment, the difference between the starting points of the vertical strips 206 and 208 is 4 cm. However, it is conceived that the lower starting points of the vertical strips 206 and 208 are staggered more or less, or not be staggered at all.

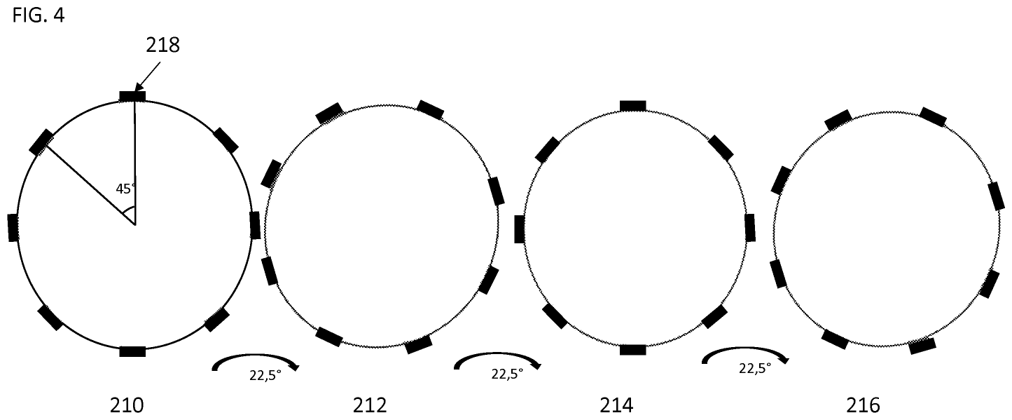

In addition to the vertical strips 206 and 208 of sensors 218, the vertical tank 200 also includes a number of sensors 218 located on horizontal rings spaced equidistantly apart on the wall of the vertical tank 200. The purpose of horizontal rings 210-216 is to maximize the ability to measure the homogeneity of the mixture across the vertical tank 200. Each of the horizontal rings 210-216 may have the same number of sensors 218. As shown in FIG. 4 and described below, the sensors 218 on each ring are offset from the sensors 218 on the adjacent ring.

FIG. 4 is an exemplary layout of sensors 218 around horizontal rings 210-216. In the illustrated embodiment, 8 sensors 218 are placed uniformly over each horizontal ring 210-216, with 45 degrees between adjacent sensors. Each horizontal ring 210-216 is rotated about the z-axis, for example by 22.5 degrees with respect to the adjacent horizontal rings 210-216. Specifically, in the illustrated embodiment horizontal ring 210 is rotated 22.5 degrees from horizontal ring 212, which is rotated 22.5 degrees from horizontal ring 214, which is rotated 22.5 degrees from horizontal ring 216. This allows for the homogeneity index of the entire mixture to be measured, and divided up into smaller regions of interest, if desired.

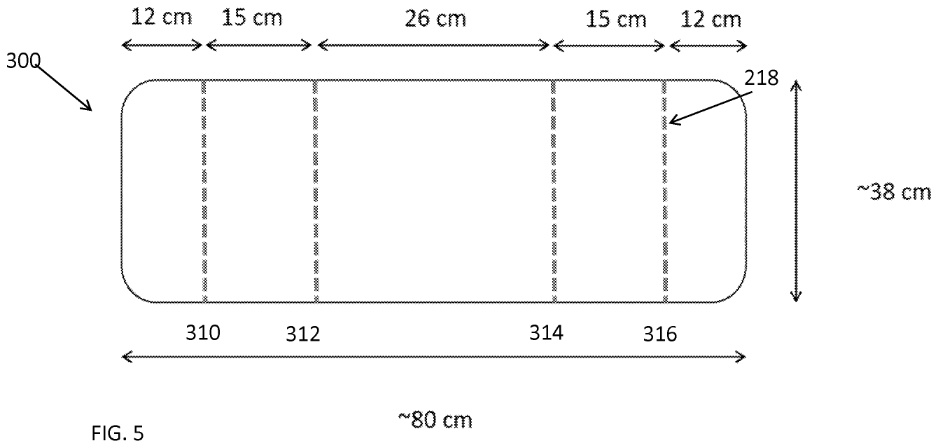

FIG. 5 is an exemplary embodiment of a horizontally oriented tank. Horizontal tank 300 may include a number of vertical rings 310-316 of sensors 218. The vertical rings 310-316 are spaced evenly along the horizontal tank 300. In the illustrated embodiment, vertical rings 310 and 312 are spaced 15 cm apart, while the two center vertical rings 312 and 314 may be spaced a further distance apart from one another. Each of the vertical rings 310-316 comprises 16 sensors distributed around the circumference of the ring.

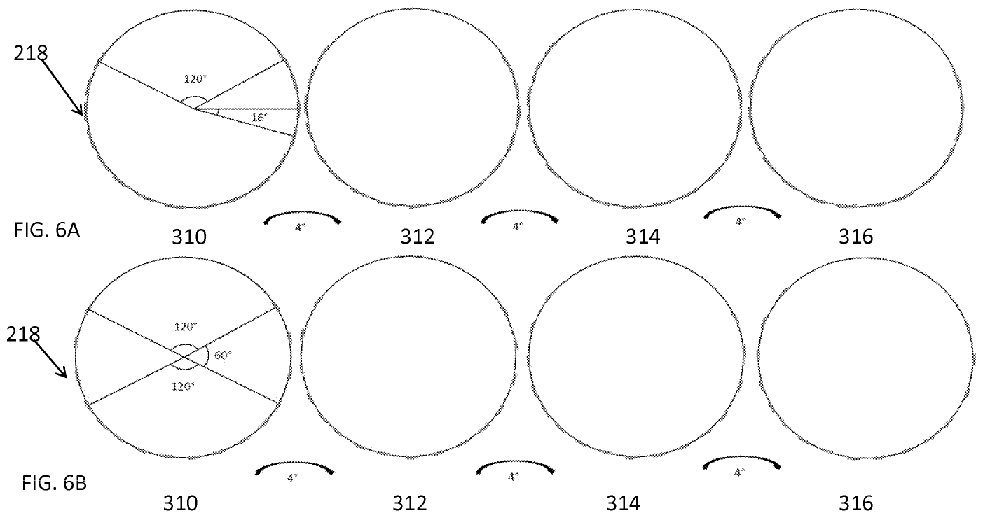

FIGS. 6A and 6B are exemplary layouts of sensors around a plurality of ring sections of a horizontally oriented tank, according to exemplary embodiments of the present disclosure. In FIG. 6A, each sensor 218 is placed at a 16 degree angle about the adjacent sensors 218. In the illustrated embodiment, 16 sensors 218 are placed on the bottom 240 degrees of the circumference of the vertical rings 310-316. This placement ensures that regions of the horizontal tank more likely to experience sedimentation have a larger number of sensors placed on the surrounding walls. Each vertical ring is rotated 4 degrees about the z-axis with respect to the adjacent ring, so that a maximum volume of the mixture, especially the volume of the mixture at the bottom of the horizontal tank 300, is covered by the sensors 218 and may be monitored without additional sensors.

FIG. 6B illustrates an alternative layout of the sensors 218 on vertical rings 310-316. In this layout, the 16 sensors 218 are still placed so they are on the bottom 240 degrees of the circumference of vertical rings 310-316. However, each 60 degree arc of the circumference has four sensors 218, including the sensors 218 on the border between 60 degree arcs. A 20 degree angle is between sensors 218 in these sections. This leaves the bottom 120 degree arc with 10 sensors 218, including the sensors 218 on the border of the 60 degree arcs. In this section, there is roughly a 13.3 degree angle between the sensors 218. Thus, the bottom part of each vertical ring 310-316 has a higher number of sensors 218. Each vertical ring is rotated 4 degrees about the z-axis with respect to the adjacent ring, so that a maximum volume of the mixture, especially the volume of the mixture at the bottom of the horizontal tank 300, is covered by the sensors 218 and may be monitored without additional sensors, as in the layout shown in FIG. 6A.

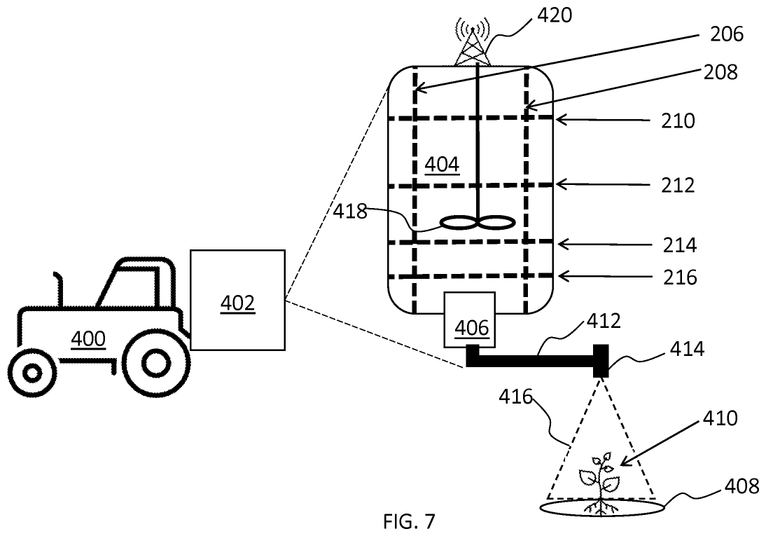

An embodiment of the disclosure is illustrated in FIG. 7. In the embodiment a vehicle 400, for traversing a field or area of agrochemical application, contains an agrochemical applicator system 402. In the embodiment shown in FIG. 7, the vehicle 400 is a tractor, however, the vehicle 400 can be an aerial drone. The agrochemical applicator system 402 can be any system as known in the art. In general, the agrochemical applicator system 402 has a vessel 404, and is outfitted with a plurality of sensors 206, 208, 210, 212, 214, 216 as discussed above with respect to FIG. 3.

A pump system 406 is in communication with the vessel 404. The pump system 406 is configured to transfer the contents of the vessel 404 to an area of application 408. As illustrated in the FIG. 7, sensors 214, 216 can be closer to the bottom of the vessel 404 as well as the pump system 406, which can be an outlet of the vessel 404. Other mechanisms of pumping the contents of the vessel 404 out can be used, for example, pressurization of the tank. In general, the area of application 408 contains a crop plant 410 for protection or a pest such as a weed or insect. The pump 406 can transfer the contents of the vessel 404 through a fluid communication means 412, e.g., a pipe or tubing, to an agrochemical applicator 414 such as a nozzle. The agrochemical applicator 414 applies the content of the vessel 404 to the area of application 408, as shown in FIG. 7, the agrochemical applicator can provide a spray 416 of the contents of the vessel 404.

The vessel 404 can optionally contain an agitator 418. The agitator 418 can be any device or mechanism which agitates or circulates the contents of the vessel 404 in order to increase the homogeneity of the contents of the vessel 404. In specific embodiments, the agrochemical applicator system 402 contains a communication device 420. The communication device 420 can relay and receive information relating to agrochemical application. Examples of such information is the raw data received from the plurality of sensors 206, 208, 210, 212, 214, 216 to a processor, or in embodiments where a processor is onboard the agrochemical applicator system 402 the communication device 420 can send a homogeneity index to the vehicle 400, or other relevant information. Conversely, the communication device 420 can receive commands for application of the contents of the vessel 400.

1. A method of monitoring formulation stability in real time, comprising:
A. loading a vessel comprising a plurality of sensors on a wall of the vessel with a composition comprising at least one agrochemical;
B. applying an electrical potential with the plurality of sensors to the contents of the vessel;
C. measuring with the plurality of sensors at least one electrical property of the contents of the vessel from the applied electric potential;
D. determining a homogeneity index score of the contents of the vessel based on the at least one electrical property; and
E. outputting a real-time report of the homogeneity index score.

2. The method of claim 1, further comprising at least one of calibrating the plurality of sensors based on a geometry of the vessel and calibrating the plurality of sensors based on a fill level of the vessel.

3. (canceled)

4. The method of claim 1, further comprising at least one of diluting the composition in the vessel with carrier liquid, and loading a second composition comprising at least one agrochemical, wherein the at least one agrochemical of the second composition is different from the at least one agrochemical of the composition.

5. (canceled)

6. The method of claim 1, further comprising agitating the vessel, optionally wherein the agitating is before or after the determining of the homogeneity index score.

7. The method of claim 6, wherein the agitating is in response to the homogeneity index score, and optionally agitating the contents of the vessel until a predetermined homogeneity index score is achieved.

8. The method of claim 1, wherein the at least one electrical property includes electrical conductivity, wherein the method further comprises applying an electrical current to the contents of the vessel.

9. The method of claim 1, further comprising at least one of
calibrating the plurality of sensors based on a geometry of an X, a Y, and a Z positional assignment for at least two of the sensors;
determining a product delivery score based on the homogeneity index score; and
recording a maximum homogenous value for the contents of the vessel.

10. (canceled)

11. (canceled)

12. (canceled)

13. The method of claim 1, further comprising:
setting a threshold value from the maximum homogeneous value of the contents of the vessel;
monitoring the homogeneity index of the contents of the vessel over time;
determining whether the homogeneity index has crossed the threshold value; and
alerting a user to agitate the contents of the vessel and/or stop transfer/application of the contents of the vessel.

14. The method of claim 1, further wherein the real-time report comprises at least one of a two-dimensional rendering of the mixture in real time, a three dimensional rendering of the mixture in real time, and/or a real time plot of the homogeneity index over time.

15. The method of claim 1, wherein the plurality of sensors comprise at least eight sensors or sensor strips and are around a circumference of the vessel, wherein a majority of the plurality of sensors are near a bottom part of the vessel or a transfer port of the vessel.

16. (canceled)

17. (canceled)

18. The method of claim 1, further comprising:
dividing the contents within the vessel into a plurality of subsections;
filtering out measurements from one or more subsections of the vessel containing a sediment or other layering; and
determining a homogeneity index of one of the plurality of subsections.

19. The method of claim 1, wherein the plurality of sensors are electrodes.

20. The method of claim 1, further comprising applying the contents of the vessel from an agrochemical applicator including a nozzle, in fluid communication with the vessel to a crop or locus thereof.

21. (canceled)

22. The method of claim 1, further comprising modifying at least one component of the composition based on the homogeneity index score, and optionally repeating A-E.

23. (canceled)

24. A system for monitoring agrochemical formulation stability in real time, comprising:
a vessel formed from at least one wall and preferably configured to hold at least 1 gallon, at least 5 gallons, at least 10 gallons, at least 100 gallons, at least 1,000 gallons, or at least 10,000 gallons;
a plurality of sensors along a wall of the vessel configured to apply an electrical potential to the contents of the vessel and measure at least one electrical property of the contents of the vessel;
a processor in communication with the plurality of sensors and configured to determine a homogeneity index score of the contents of the vessel based on the at least one electrical property; and
a composition contained within the vessel, wherein the composition contains at least one agrochemical active ingredient;
wherein the vessel comprises at least one agitator configured to agitate the contents of the vessel; and
wherein the processor is configured to determine at least one of
a product delivery score based on the homogeneity index score, and
a maximum homogenous value for the contents of the vessel.

25. (canceled).

26. The system of claims 24, wherein the plurality of sensors are configured to measure electrical conductivity, and wherein the plurality of sensors are configured to apply an electrical current to the contents of the vessel.

27. (canceled)

28. (canceled)

29. (canceled)

30. The system of claim 24, further comprising at least one of
a memory space in communication with a processor or the plurality of sensors, and configured to store information from the plurality of sensors and/or processor; and
a display capable of displaying the homogeneity index score or information derived therefrom.

31. (canceled)

32. The system of claim 30, wherein the display provides at least one of a two-dimensional rendering of the contents of the vessel in real time, a three dimensional rendering of the contents of the vessel in real time, and/or a real time plot of the homogeneity index over time.

33. The system of claim 24, wherein the plurality of sensors comprise at least six sensors are around a circumference of the vessel, wherein the sensors comprise electrodes; and
wherein the plurality of sensors are near a bottom part of the vessel or a transfer port of the vessel.

34. (canceled)

35. (canceled)

36. (canceled)

37. The system of claim 24, further comprising an agrochemical applicator including a nozzle, in fluid communication with the vessel.

38. The system of claim 37, wherein a processor controls application of the contents of the vessel from the agrochemical applicator based on the homogeneity index score or information derived therefrom.

39. (canceled)

40. The system of claim 24, further comprising a second vessel in communication with the vessel and configured to modify the contents of the vessel based on the homogeneity index score or information derived therefrom.
